(19) United States
(12) Patent Application Publication
(10) Pub. No.: US 2025/0120272 A1
(43) Pub. Date: Apr. 10, 2025

(54) DISPLAY DEVICE

(71) Applicant: SAMSUNG DISPLAY CO., LTD., Yongin-si (KR)

(72) Inventors: BONGIL KANG, Yongin-si (KR); MIN-HONG KIM, Yongin-si (KR); JUNGMOK PARK, Yongin-si (KR)

(21) Appl. No.: 18/888,411

(22) Filed: Sep. 18, 2024

(30) Foreign Application Priority Data
Oct. 6, 2023 (KR) 10-2023-0133019

(51) Int. Cl. H10K 59/131; H10K 59/40

(52) U.S. Cl. CPC H10K 59/131; H10K 59/40

(57) ABSTRACT

Provided is a display device including a display layer to display an image and a sensor layer disposed on the display layer to sense an input. The display layer includes a base layer including a first region and a second region adjacent to the first region defined in the base layer, a plurality of pixels disposed in the first region of the base layer and including a cathode, and a power electrode disposed in the second region of the base layer and connected to the cathode at a connection region. The sensor layer includes a plurality of sensing electrode and an inspection line overlapping the connection region.

### CROSS-REFERENCE TO RELATED APPLICATIONS

This application claims priority under 35 U.S.C. § 119 to Korean Patent Application No. 10-2023-0133019 filed on Oct. 6, 2023, in the Korean Intellectual Property Office, the disclosures of which are incorporated by reference herein in their entireties.

### BACKGROUND

### 1. Technical Field

The present disclosure generally relates to a display device. More particularly, the present disclosure relates to a display device having improved reliability.

### 2. Description of the Related Art

A display device is a component of multimedia electronic devices, which include TVs, smartphones, tablets, PCs, game consoles, and navigation systems. Along with a standard input method like a button, keyboard, or mouse, display devices may also have an input sensor that offers a touch-based input manner that allows a user to intuitively, conveniently, and easily submit information or a command.

### SUMMARY

Embodiments of the present disclosure described herein relate to a driving device having improved reliability.

According to an embodiment of the present disclosure, a display device may include a display layer to display an image and a sensor layer disposed on the display layer and configured to sense an input. The display layer may include a base layer including a first region and a second region adjacent to the first region, wherein the first region and the second region are defined in the base layer, a plurality of pixels disposed in the first region of the base layer and including a cathode at a connection region, and a power electrode disposed in the second region of the base layer and connected to the cathode. The sensor layer may include a plurality of sensing electrode and an inspection line which overlaps the connection region.

The connection region may surround at least a portion of the first region.

A plurality of inspection lines may be provided, and the plurality of inspection lines may include a first inspection line and a second inspection line, and the first inspection line and the second inspection line may overlap the connection region.

The first inspection line and the second inspection line may be spaced apart from each other, and the first region is disposed between the first inspection line and the second inspection line, when viewed in a plan view.

The first inspection line may surround at least a portion of the first region and the second inspection line may be spaced apart from the first region while interposing the first inspection line between the second inspection line and the first region, when viewed in a plan view.

A width of the inspection line may be equal to a width of the connection region.

A width of the inspection line may be smaller than a width of the connection region.

A width of the inspection line may be greater than a width of the connection region.

A plurality of inspection lines may be provided, extend in a first direction, and be arranged in a second direction crossing the first direction.

A plurality of connection regions may be provided, and a plurality of inspection lines may be provided, and the plurality of inspection lines may overlap the plurality of connection regions in a one-to-one correspondence.

The power electrode may include a first electrode layer, a second electrode layer disposed on the first electrode layer and connected to the first electrode layer, and a third electrode layer disposed on the second electrode layer and connected to the second electrode layer, and the cathode may be in direct contact with the third electrode layer.

The inspection line may overlap the third electrode layer in a thickness direction, and the cathode may extend from the first region to the second region.

According to an embodiment, a display device may include a base layer including a first region and a second region surrounding the first region, wherein the first region and the second region are defined in the base layer, a power electrode disposed in the second region of the base layer to receive a power supply voltage, a light emitting element disposed in the first region of the base layer and including an anode, a light emitting layer disposed on the anode, and a cathode disposed on the light emitting layer and electrically connected to the power electrode, and an inspection line overlapping a connection region at which the cathode and the power electrode are connected to each other.

The power electrode may include a first electrode layer, a second electrode layer disposed on the first electrode layer and connected to the first electrode layer, and a third electrode layer disposed on the second electrode layer and connected to the second electrode layer, and the cathode may be in direct contact with the third electrode layer.

The third electrode layer may be disposed on a layer the same as a layer of the anode and include the same material, and the inspection line may overlap the third electrode layer in the thickness direction.

A plurality of inspection lines may be provided, the plurality of inspection lines may include a first inspection line a second inspection line, and the first inspection line and the second inspection line overlap the connection region.

The first inspection line and the second inspection line may be spaced apart from each other, and the first region is disposed between the first inspection line and the second inspection line, when viewed in a plan view.

The first inspection line may surround at least a portion of the first region and the second inspection line may be spaced apart from the first region while interposing the first inspection line between the second inspection line and the first region, when viewed in a plan view.

A plurality of connection regions may be provided, and a plurality of inspection lines may be provided, and the plurality of inspection lines may overlap the plurality of connection regions in a one-to-one correspondence.

According to an embodiment, a display device may comprise a base layer, a power electrode disposed on the base layer to receive a power supply voltage, a light emitting element disposed on the base layer and including an anode, a light emitting layer, and a cathode electrically connected to the power electrode, an inspection line which overlaps a connection region at which the cathode and the power electrode are connected to each other, and an encapsulation layer disposed on the light emitting layer to cover the light emitting element, wherein the inspection line is disposed on the encapsulation layer.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device 1000 according to an embodiment of the present disclosure.

FIG. 2 is a block diagram of a display device according to an embodiment of the present disclosure.

FIG. 3 is a plan view of a display layer according to an embodiment of the present disclosure.

FIG. 4 is a plan view of a sensor layer according to an embodiment of the present disclosure.

FIG. 5A is a cross-sectional view of a display panel taken line along I-I′ of FIG. 3 and FIG. 4 according to an embodiment of the present disclosure.

FIG. 5B is a plan view of a cathode according to an embodiment of the present disclosure.

FIG. 6 is a cross-sectional view of a display panel taken line along I-I′ of FIG. 3 and FIG. 4 according to an embodiment of the present disclosure.

FIG. 7 is a cross-sectional view illustrating a display panel taken line along I-I′ of FIG. 3 and FIG. 4 according to an embodiment of the present disclosure.

FIG. 8 is a plan view of a sensor layer according to an embodiment of the present disclosure.

FIG. 9 is a cross-sectional view of a display panel taken line along I-I′ of FIG. 3 and FIG. 4 according to an embodiment of the present disclosure.

FIG. 10 is a perspective view illustrating some components of a display panel according to an embodiment of the present disclosure.

FIG. 11 is a perspective view illustrating some components of a display panel according to an embodiment of the present disclosure.

FIG. 12 is a perspective view illustrating some components of a display pane, according to an embodiment of the present disclosure.

### DETAILED DESCRIPTION

In the specification, the expression that a first component (or region, layer, part, portion, etc.) is “on”, “connected to”, or “coupled to” a second component means that the first component is directly on, connected to, or coupled to the second component or means that a third component is interposed therebetween.

The same reference numeral will be assigned to the same component. In addition, in drawings, thicknesses, proportions, and dimensions of components may be exaggerated to describe the technical features effectively. The term “and/or” includes any and all combinations of one or more of associated components

Although the terms “first”, “second”, etc. may be used to describe various components, the components should not be construed as being limited by the terms. The terms are only used to distinguish one component from another component. For example, without departing from the scope and spirit of the invention, a first component may be referred to as a second component, and similarly, the second component may be referred to as the first component. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and are described with reference to a direction indicated in the drawing.

It will be further understood that the terms “comprises,” “comprising,” “includes,” or “including,” or “having” specify the presence of stated features, numbers, steps, operations, components, parts, or the combination thereof, but do not preclude the presence or addition of one or more other features, numbers, steps, operations, components, components, and/or the combination thereof.

The terms “part” and “unit” refer to a software component or a hardware component to perform a specific function. The hardware component may include field-programmable gate array (FPGA) or an application-specific integrated circuit (ASIC). Software components may indicate data used by executable codes and/or executable codes in a storage medium which is able to be addressed. Accordingly, software components may be, for example, object-oriented software components, class components, and task components, and may include processes, functions, properties, procedures, subroutines, program code segments, driver data, firmware, micro-codes, circuits, data, database, data structures, tables, arrangements or variables.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the present disclosure will be described with reference to accompanying drawings.

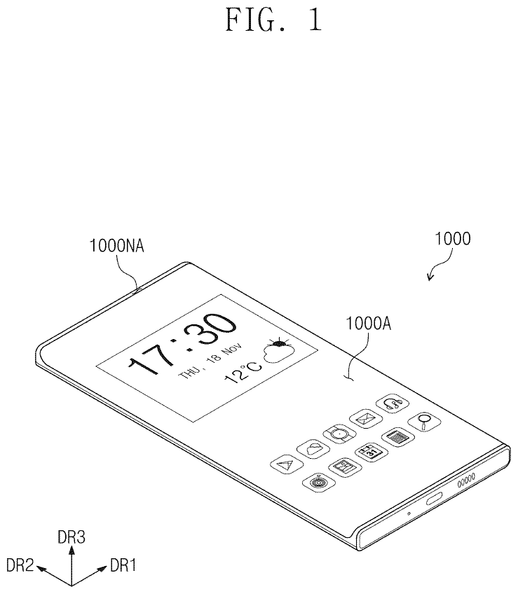

FIG. 1 is a perspective view of a display device 1000 according to an embodiment of the present disclosure.

Referring to FIG. 1, the display device 1000 refer to a device which is activated in response to an electrical signal. For example, the display device 1000 may be a cellular phone, a foldable phone, a laptop computer, a television, a tablet, a vehicle navigation system, a game console, or a wearable device, but the present disclosure is not limited thereto. FIG. 1 illustrates that the display device 1000 is the cellular phone.

The display device 1000 may include an active region 1000A and a peripheral region 1000NA defined in the display device 1000. The display device 1000 may display an image through the active region 1000A. The active region 1000A may include a surface defined by a first direction DR1 and a second direction DR2. The peripheral region 1000NA may surround the active region 1000A. In this case, the display device 1000 may be a rectangular shape, but in another example, the display device 1000 may be a triangular, rectangular, circular, or any polygonal shape.

The thickness direction of the display device 1000 may be parallel to a third direction DR3 crossing the first direction DR1 and the second direction DR2. Accordingly, front surfaces (or top surfaces) and rear surfaces (or bottom surfaces) of members constituting the display device 1000 may be defined in the third direction DR3.

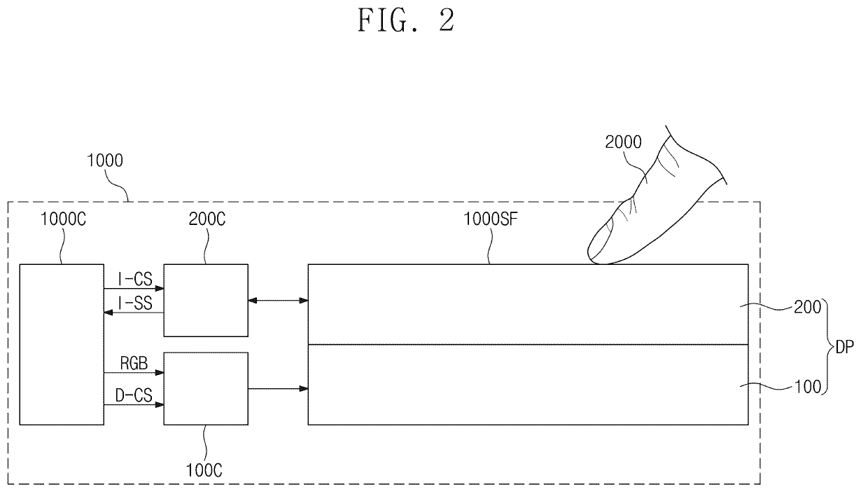

FIG. 2 is a block diagram of the display device 1000, according to an embodiment of the present disclosure.

Referring to FIG. 2, the display device 1000 may include a display panel DP, a display driver 100C, a sensor driver 200C, and a main driver 1000C. The display panel DP may include a display layer 100 and a sensor layer 200 disposed on the display layer 100

The display layer 100 may be a component which substantially generates an image. The display layer 100 may be an emissive-type display layer. For example, the display layer 100 may be an organic light emitting display layer, an inorganic light emitting display layer, an organic-inorganic display layer, a quantum dot display layer, a micro-LED display layer, or a nano-LED display layer.

The sensor layer 200 may be disposed on the display layer 100. The sensor layer 200 may sense an external input 2000 applied thereto from an outside. The external input 2000 may include all of input units to provide a change in capacitance. For example, the sensor layer 200 may sense an input made by an active-type input unit to provide a driving signal, as well as a passive-type input unit, such as a human body, of a user. In another example, the external input 2000 may be an electrical pencil or the like.

The main driver 1000C may control the overall operation of the display device 1000. For example, the main driver 1000C may control the operations of the display driver 100C and the sensor driver 200C. The main driver 1000C may include at least one microprocessor, and may be referred to as a “host”. The main driver 1000C may be referred to as an application processor, a central processing unit, or a main processor.

The display driver 100C may control the display layer 100. The display driver 100C may receive image data RGB and a control signal D-CS from the main driver 1000C. The control signal D-CS may include various signals. For example, the control signal D-CS may include an input vertical synchronization signal, an input horizontal synchronization signal, a main clock, and a data enable signal. The display driver 100C may generate a vertical synchronization signal and a horizontal synchronization signal for controlling a timing to provide a signal to the display layer 100, based on the control signal D-CS.

The sensor driver 200C may control the sensor layer 200. The sensor driver 200C may receive image data RGB and a control signal I-CS from the main driver 1000C. The control signal I-CS may include a mode determining signal for determining a driving mode of the sensor driver 200C, and a clock signal.

The sensor driver 200C may calculate information on coordinates of a input, based on a signal received from the sensor layer 200, and may provide a coordinate signal I-SS having the coordinate information to the main driver 1000C. The sensor driver 200C may calculate coordinate information of an input made while being spaced apart from a surface 1000SF, as well as coordinate information of an input made in contact with the surface 1000SF of the display device 1000. The input made while being spaced apart from the surface 1000SF may be referred to as a hovering input.

The main driver 1000C executes an operation corresponding to a user input, in response to the coordinate signal I-SS. For example, the main driver 1000C may operate the display driver 100C such that a new application image is displayed on the display layer 100.

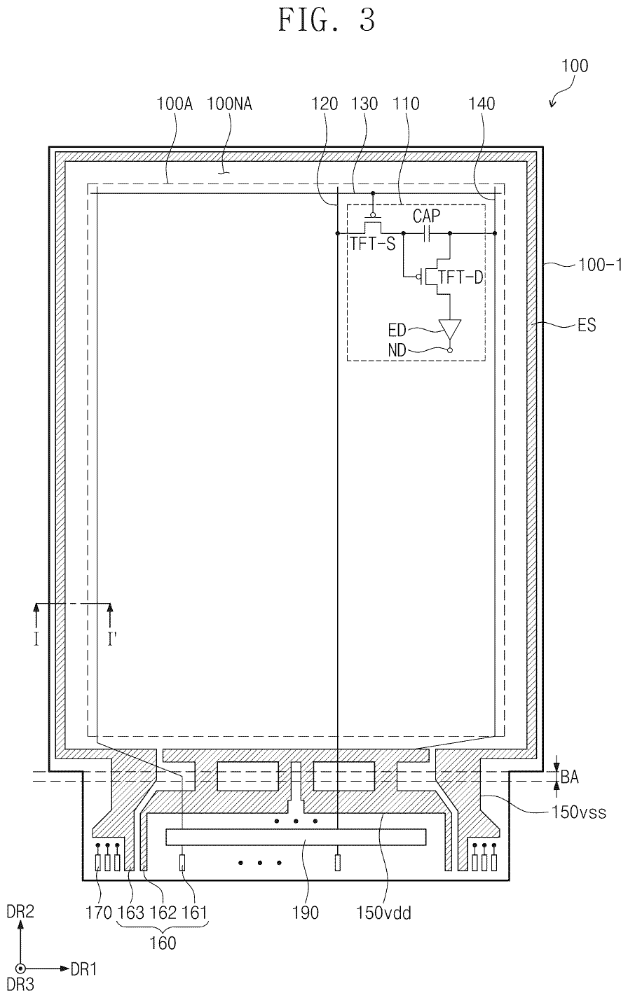

FIG. 3 is a plan view illustrating the display layer 100, according to an embodiment of the present disclosure.

Referring to FIG. 3, the display layer 100 includes a first region 100A and a second region 100NA. The first region 100A may be corresponding to the active region 1000A (see FIG. 1) of the display device 1000 (see FIG. 1), and the second region 100NA may be corresponding to the peripheral region 1000NA (see FIG. 1) of the display device 1000 (see FIG. 1). In the present disclosure, the wording “a region/part correspond to a region/part” refers to that the region/part is overlapped with the region/part ”, and does not refer to that the region/part has an area the same as an area of the region/part.

The first region 100A may be activated in response to an electrical signal, and may be referred to as an active region. For example, the first region 100A may be a region for displaying an image. The second region 100NA may surround the first region 100A. A driving circuit or a driving line may be disposed in the second region 100NA to drive the first region 100A, and may be referred to as a peripheral region.

FIG. 3 is a plan view illustrating the state of the display layer 100 before the display layer 100 is assembled. In the assembling process, the display region may be bent such that the bending region BA defined in the second region 100NA has a specific curvature. Accordingly, parts (e.g., regions) disposed on/down the bending region BA face each other.

The display layer 100 may include a base layer 100-1, a plurality of pixels 110, a plurality of signal lines 120, 130, and 140, a first power electrode 150vdd, a second power electrode 150vss, a plurality of display pads 160, and a plurality of sensing pads 170.

The base layer 100-1 may include a glass substrate, an organic/inorganic composite substrate, a silicon substrate, or a synthetic film. The synthetic film may include a thermosetting resin. The base layer 100-1 may have a multi-layer structure. For example, the base layer 100-1 may have a three-layer structure of a synthetic resin layer, an adhesive layer, and a synthetic resin layer. In particular, the synthetic resin layer may be a polyimide-based resin layer, and the material of the synthetic resin layer is not specifically limited. The synthetic resin layer may include at least one of an acrylic resin, a methacrylic resin, a polyisoprene resin, a vinyl resin, an epoxy resin, a urethane resin, a cellulose resin, a siloxane resin, a polyamide resin, or a perylene resin.

A partial region of the base layer 100-1 included in the first region 100A may also be referred to as the first region, and another partial region of the base layer 100-1 included in the second region 100NA may also be referred to as the second region.

The signal lines 120, 130, and 140 are connected to the pixels 110 to transmit electrical signals to the pixels 110. FIG. 3 illustrates that the signal lines 120, 130, and 140 include a data line 120, a scan line 130, and a power line 140, respectively. However, in another example, the signal lines 120, 130, and 140 may further include at least one of an initialization voltage line and a light emitting control line, but the present disclosure is not limited to any one embodiment. In this case, the data line 120 may extend along the second direction DR2, the scan line 130 may extend along the first direction DR1 crossing the second direction DR2, and the power line 140 may extend along the second direction DR2. In particular, the data line 120 may be spaced apart from the power line 140 along the first direction DR1.

The pixels 110 may be disposed in the first region 100A. According to an embodiment, the equivalent circuit diagram of one pixel 110 of a plurality of pixels are enlarged and illustrated.

The plurality of pixel 110 may be disposed in the first region 100A and include a first transistor TFT-S, a second transistor TFT-D, a capacitor CAP, and a light emitting element ED. However, in another example, the pixel 110 may include electronic elements having various components and arrangements. In this case, the pixel 110 may have an equivalent circuit including seven transistors and one capacitor, and the equivalent circuit of the pixel 110 may be modified in various forms.

The first transistor TFT-S may be a switching transistor that controls on/off of the pixel 110. The first transistor TFT-S may be a driving transistor that transmits or blocks a data signal transmitted through the data line 120 in response to a scan signal transmitted through the scan line 130.

One end of the capacitor CAP may be connected to the first transistor TFT-S, and the other end of the capacitor CAP may be connected to the power line 140. The capacitor CAP may charge an amount of charges corresponding to a difference between a data signal transmitted from the first transistor TFT-S and a first power signal applied to the power line 140.

The second transistor TFT-D may be disposed between the capacitor CAP and the light emitting element ED. In this case, the second transistor TFT-D may be connected to the first transistor TFT-S, the capacitor CAP, and the light emitting element ED. The second transistor TFT-D may control a driving current flowing through the light emitting element ED, in response to the amount of charges stored in the capacitor CAP. A time (turn-on time) for turning on the second transistor TFT-D may be determined depending on amount of charges charged in the capacitor CAP. The second transistor TFT-D may provide the first power signal (or referred to as a first power voltage or a voltage ELVDD) transmitted through the power line 140 during the turn-on time to the light emitting element ED.

The light emitting element ED may be disposed between the second transistor TFT-D and the node ND and may generate light or control the amount of light depending on an electrical signal. For example, the light emitting element ED may include an organic light emitting element, a quantum dot light emitting element, a micro-LED light emitting element, or a nano-LED light emitting element.

The node ND electrically connected to the light emitting element ED may receive a second power signal (or referred to as a second power voltage or an ELVSS voltage). The second power signal may have a different level from the first power signal. A driving current corresponding to a difference between the electrical signal provided from the second transistor TFT-D and the second power signal flows through the light emitting element ED, and the light emitting element ED may generate light corresponding to the driving current.

The first power electrode 150vdd may be disposed in the second region 100NA. In this case, the first power electrode 150vdd may overlap the bending region BA. The first power electrode 150vdd may be electrically connected to the power line 140. Although one power line 140 is illustrated in FIG. 3 for brevity, a plurality of power lines 140 may be provided, and all of the plurality of power lines 140 may be electrically connected to the first power electrode 150vdd.

The second power electrode 150vss and a power electrode ES electrically connected to the second power electrode 150vss may be disposed in the second region 100NA. In this case, the second power electrode 150vss may overlap the bending region BA. The power electrode ES may surround at least a portion of the first region 100A. In this case, the power electrode ES may be disposed along the edge of the base layer 100-1. As depicted in FIG. 3, the power electrode ES surrounds a right portion, a left portion, and a top portion of the base layer 1000-1. The node ND electrically connected to the light emitting element ED may be electrically connected to the power electrode ES. For example, the cathode (or common electrode) of the light emitting element ED may be directly connected to the power electrode ES. A second power signal may be provided to the second power electrode 150vss and the power electrode ES. The cathode of the light emitting element ED may be electrically connected to the second power electrode 150vss and the power electrode ES to receive the second power signal.

The display pads 160 may be disposed adjacent to the first power electrode 150vdd and the second power electrode 150vss and may include a plurality of first pad 161, a second pad 162, and a third pad 163. Each of the plurality of first pads 161 may be provided to be connected to the data lines 120, respectively. The second pad 162 may be electrically connected to the power line 140 through the first power electrode 150vdd. The second pad 162 may be a portion of the first power electrode 150vdd. The third pad 163 may be electrically connected to the light emitting element ED through the second power electrode 150vss. The third pad 163 may be a portion of the second power electrode 150vss. In this case, the first pad 161, the second pad 162, and the third pad 163 may be spaced apart from each other along the first direction DR1.

The display layer 100 may provide electrical signals provided from the outside to the pixels 110 through the display pads 160. Meanwhile, the display pads 160 may further include pads to receive electrical signals other than the first pad 161, the second pad 162, and the third pad 163, but the present disclosure is not limited to any one embodiment.

The plurality of sensing pads 170 may be electrically connected to sensing electrodes of a sensor layer to be described later. The plurality of sensing pads 170 may be disposed adjacent to the display pads 160. In this case, the plurality of the sensing pads 170 may be disposed adjacent to the third pads 163. However, the present disclosure is not limited thereto, and an arrangement relationship between the sensing pads 170 and the display pads 160 may be variously modified.

The driving chip 190 may be mounted on the second region 100NA of the display layer 100. In particularly, the driving chip 190 may be interposed between the plurality of the first pads 161 and the first power electrode 150vdd. The driving chip 190 may be a data driving circuit in the form of a chip. However, this is provided only for the illustrative purpose, and the driving chip 190 may be separately mounted from the display layer 100. In this case, the driving chip 190 may be electrically connected to the display pads 160 through the film.

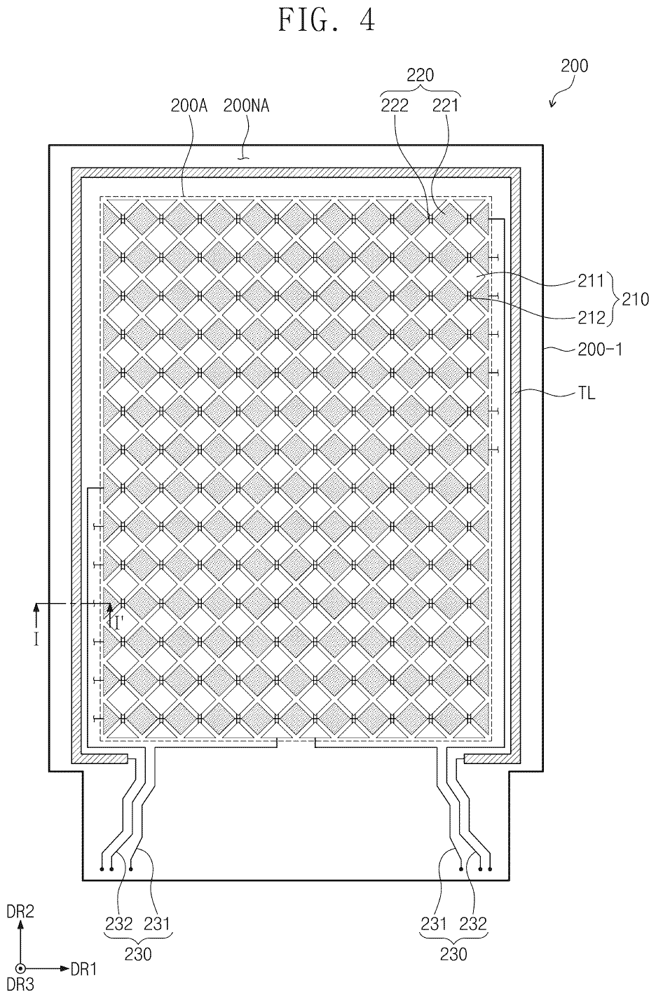

FIG. 4 is a plan view illustrating a sensor layer 200, according to an embodiment of the present disclosure.

Referring to FIG. 4, the sensor layer 200 includes a first region 200A and a second region 200NA, and the first region 200A may be corresponding to the active region 1000A (see FIG. 1) of the display device 1000 (see FIG. 1) and second region 200NA may be corresponding to the peripheral region 1000NA (see FIG. 1) of the display device 1000 (see FIG. 1). In this case, the first region 200A of the sensor layer 200 may overlap the first region 100A of the display layer 100. The first region 200A may be a region that is activated in response to an electrical signal. For example, the first region 200A may be a region to sense an input, and may be referred to as a sensing region. The second region 200NA may surround the first region 200A.

The sensor layer 200 may include a base insulating layer 200-1, first sensing electrodes 210, second sensing electrodes 220, sensing lines 230, and an inspection line TL. The first sensing electrodes 210 and the second sensing electrodes 220 may be disposed in the first region 200A, and the sensing lines 230 and the inspection line TL may be disposed in the second region 200NA. Information on an external input may be obtained through a change in mutual capacitance between the first sensing electrodes 210 and the second sensing electrodes 220.

The first sensing electrodes 210 may be arranged in the first direction DR1, and may extend in the second direction DR2. The first sensing electrodes 210 may include first sensing patterns 211 and first connection patterns 212. Each of the first connection patterns 212 may electrically connect two adjacent first sensing patterns 211 together. The two adjacent first sensing patterns 211 may be connected to each other through each of the first connection patterns 212, but the present disclosure is not limited thereto.

The second sensing electrodes 220 may extend in the first direction DR1, and the second sensing electrodes 220 may be arranged in the second direction DR2. The second sensing electrodes 220 may include second sensing patterns 221 and second connection patterns 222. The two first connection patterns 212 and one second connection pattern 222 may insulate and cross each other. The second sensing patterns 221 and the second connection patterns 222 included in one second sensing electrode 220 may have an integral shape connected to each other. Accordingly, the second sensing patterns 221 may be referred to as a first part, and the second connection patterns 222 may be referred to as a second part.

The shape and arrangement relationship of the first sensing electrodes 210 and the second sensing electrodes 220 illustrated in FIG. 4 are provided only for the illustrative purpose. The shape and arrangement relationship of the first sensing electrodes 210 and the second sensing electrodes 220 constituting the sensor layer 200 are not limited to those illustrated in FIG. 4.

Each of the sensing lines 230 and an inspection line TL may be electrically connected to the sensing pads 170 (refer to FIG. 3) through contact holes, respectively.

The sensing lines 230 may include first sensing lines 231 and second sensing lines 232. Each of the first sensing lines 231 may be electrically connected to each of the first sensing electrodes 210, respectively. Each of the second sensing lines 232 may be electrically connected to each of the second sensing electrodes 220, respectively. In this case, at least some of the first sensing lines 231 may be connected to the bottom portion of the first sensing electrodes 210. In addition, some of the second sensing lines 232 may be connected to the left side of the second sensing electrodes 220, and the other of the second sensing lines 232 may be connected to the right side of the second sensing electrodes 220. However, the connection relationship between the first sensing lines 231 and the first sensing electrodes 210 and the connection relationship between the second sensing lines 232 and the second sensing electrodes 220 are not limited to the example illustrated in FIG. 4.

The inspection line TL may surround at least a portion of the first region 200A. In this case, the inspection line TL may surround the left and right sides and upper portion of the first region 200A of the sensor layer 200. In addition, the inspection line TL may partially surround the bottom portion of the first region 200A. The inspection line TL may be spaced apart from the first region 200A while the sensing lines 230 may be interposed between two inspection lines TL along the first direction DR1. One end and an opposite end of the inspection line TL may be connected to the corresponding sensing pads 170, respectively. However, in another example, one end of the inspection line TL may be electrically connected to the sensing pad 170, and an opposite end of the inspection line TL may be floated.

When the cathode of the light emitting element ED (see FIG. 3) is not sufficiently connected to the power electrode ES (see FIG. 3), the cathode fails to sufficiently block noise caused in the circuit layer of the display layer 100 (see FIG. 3), which exerts an influence on a capacitance measured in the sensor layer 200. In this case, the sensor layer 200 may erroneously operate.

According to an embodiment of the present disclosure, inspection may be made regarding whether the cathode of the light emitting element ED and the power electrode ES are stably connected to each other through the inspection line TL. A subsequent process may be performed depending on the connection state between the cathode and the power electrode ES. For example, when the connection state is determined as being defective, a repair process may be performed. Alternatively, if repair process is not possible or difficult, the manufacturing process for that display panel may be terminated. Accordingly, deterioration of touch performance resulting from the failure in the connection between the cathode and the power electrode ES may be prevented. Accordingly, the reliability for the display device 1000 (see FIG. 1) may be improved.

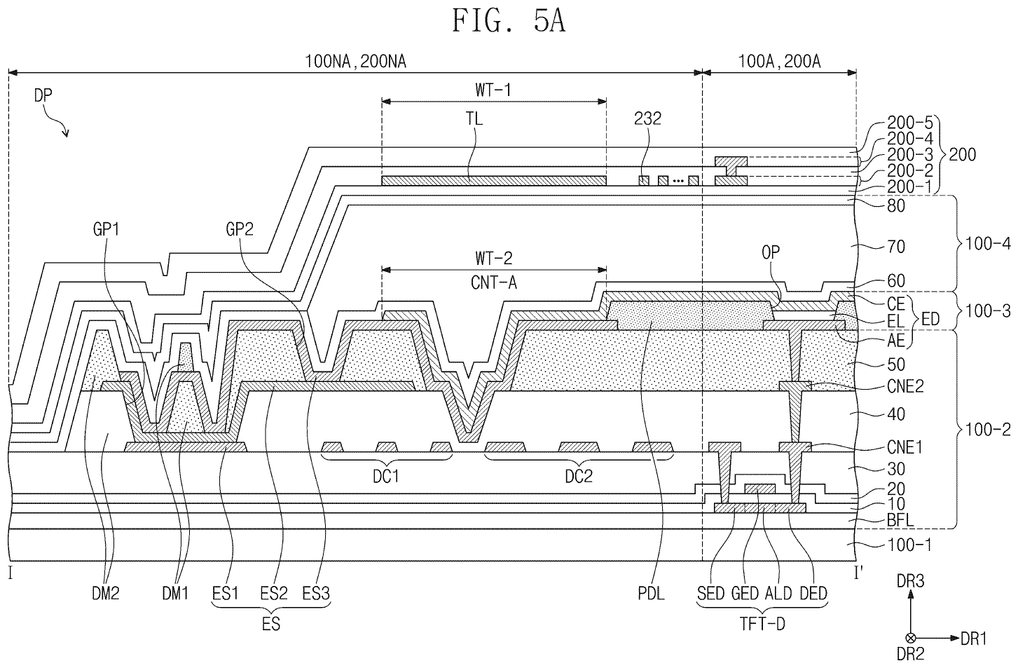

FIG. 5A is a cross-sectional view of the display panel DP taken line along I-I′ of FIG. 3 and FIG. 4, according to an embodiment of the present disclosure. FIG. 5B is a plan view of a cathode, according to an embodiment of the present disclosure. FIG. 5A illustrates a cross-sectional view of the display panel DP including the cross-section of the display layer 100 taken line along I-I′ illustrated in FIG. 3, and the cross-section of the sensor layer 200 taken line along I-I′ of FIG. 4.

Referring to FIGS. 3, 4, and 5A, the display panel DP may include the display layer 100 and the sensor layer 200. The display layer 100 may include a base layer 100-1, a circuit layer 100-2, a light emitting element layer 100-3, and an encapsulation layer 100-4, and the base layer 100-1, the circuit layer 100-2, the light emitting element layer 100-3, and the encapsulation layer 100-4 may be sequentially disposed in the third direction DR3 (e.g., thickness direction).

A buffer layer BFL may be disposed on the base layer 100-1, and the second transistor TFT-D may be disposed on the buffer layer BFL. In this case, the buffer layer BFL may be interposed between the base layer 100-1 and the second transistor TFT-D. The second transistor TFT-D may include an active region ALD, a source region SED, a drain region DED, and a control electrode GED.

The active region ALD, the source region SED, and the drain region DED may be formed from the semiconductor pattern. The source region SED and the drain region DED may extend in opposite directions from the active region ALD when viewed in a cross-sectional view. In this case, the source region SED may be disposed on the opposite side of the drain region DED with respect to the control electrode GED. In addition, the control electrode GED may overlap the active region ALD in the third direction DR3 (e.g., thickness direction).

FIG. 5A illustrates only some semiconductor patterns, and semiconductor patterns may be further disposed in other regions. The semiconductor patterns may be arranged in a specific rule while crossing pixels. The semiconductor patterns may have a different electrical property depending on whether doped. The semiconductor patterns may include a first region having higher conductivity and a second region having lower conductivity. The first region may be doped with N-type dopants or P-type dopants. A P-type transistor may include a doping region doped with the P-type dopant, and an N-type transistor may include a doping region doped with the N-type dopant. The second region may be a non-doping region or may be a region doped at a concentration lighter than the concentration of the first region.

The conductivity of the first region may be greater than the conductivity of the second region, and the first region may substantially serve as an electrode or a signal line. The second region may actually correspond to an active region (or channel) of a transistor. In other words, a portion of the semiconductor pattern may be an active region ALD of a transistor, another portion of the semiconductor pattern may be the source region SED or the drain region DED of the transistor, and still another portion of the semiconductor pattern may be a connection electrode or a connection signal line.

The active region ALD, the source region SED, and the drain region DED may be formed on the buffer layer BFL. The buffer layer BFL may provide a modified surface to the semiconductor pattern. In this case, the semiconductor pattern may have a higher adhesive force to the buffer layer BFL, as compared to when the semiconductor pattern is directly formed on the base layer 100-1. In addition, the buffer layer BFL may function as a barrier layer to protect the bottom surface of the semiconductor pattern. In this case, the buffer layer BFL may block contaminants or moisture generated in the base layer 100-1 itself or introduced through the base layer 100-1 from being infiltrated into the semiconductor pattern. Thus, the buffer layer BLF may protect the second transistor TFT-D.

A first insulating layer 10 may be disposed on the buffer layer BFL. In this case, the first insulating layer 10 may cover the active region ALD, the source region SED, the drain region DED of the second transistor TFT-D. The first insulating layer 10 may be commonly provided in a plurality of pixels to cover the semiconductor pattern. The first insulating layer 10 may be an inorganic layer and/or an organic layer, and may have a single-layer or multilayer structure. The first insulating layer 10 may include at least one of an aluminum oxide, a titanium oxide, a silicon oxide, a silicon nitride, a silicon oxynitride, a zirconium oxide, or hafnium oxide. According to the present embodiment, the first insulating layer 10 may be a single-layer silicon oxide layer. The insulating layer of a circuit layer 100-2, which is to be described below, in addition to the first insulating layer 10, may be an inorganic layer and/or an organic layer, and may have a single-layer structure or a multi-layer structure. The inorganic layer may include at least one of the materials described above, but the present disclosure is not limited thereto.

The control electrode GED is disposed on the first insulating layer 10. The control electrode GED may be a portion of a metal pattern. The control electrode GED may overlap the active region ALD along the third direction DR3. In the process of doping the semiconductor pattern, the control electrode GED may function as a mask.

A second insulating layer 20 is disposed on the first insulating layer 10 and may cover the control electrode GED of the second transistor TFT-D. The second insulating layer 20 may commonly overlap the pixels. The second insulating layer 20 may be an inorganic layer and/or an organic layer, and may have a single-layer structure or multi-layer structure. The second insulating layer 20 may include at least one of silicon oxide, silicon nitride, or silicon oxynitride. According to an embodiment, the second insulating layer 20 may have a multi-layer structure including a silicon oxide layer and a silicon nitride layer.

A third insulating layer 30 may be disposed on the second insulating layer 20. The third insulating layer 30 may have a single-layer structure or a multi-layer structure. According to an embodiment, the third insulating layer 30 may have a multi-layer structure including a silicon oxide layer and a silicon nitride layer.

A first connection electrode CNE1 may be disposed on the third insulating layer 30. The first connection electrode CNE1 may be electrically connected to the drain region DED of the second transistor TFT-D or the source region SED of the second transistor TFT-D through a contact hole penetrating the first, second, and third insulating layers 10, 20, and 30.

The fourth insulating layer 40 may be disposed on the third insulating layer 30. The fourth insulating layer 40 may be an organic layer. The second connection electrode CNE2 may be disposed on the fourth insulating layer 40. The second connection electrode CNE2 may be connected to the first connection electrode CNE1 through a contact hole penetrating the fourth insulating layer 40. The fifth insulating layer 50 may be disposed on the fourth insulating layer 40. The fifth insulating layer 50 may be an organic layer.

The circuit layer 100-2 may further include a first driving circuit DC1 and a second driving circuit DC2. The first driving circuit DC1 and the second driving circuit DC2 may include a plurality of thin film transistors formed through the same fabrication process as the driving circuit of the pixel. Although FIG. 5A illustrates the first driving circuit DC1 and the second driving circuit DC2 are disposed in the second region 100NA of the display layer 100 and second region 200NA of the sensor layer 200, the present disclosure is not particularly limited thereto. For example, to reduce the width of the second region 100NA, at least some of the first driving circuit DC1 and the second driving circuit DC2 may be disposed in the first region 100A, 200A of the display layer 100 and the sensor layer 200.

The circuit layer 100-2 may further include the power electrode ES. The power electrode ES may be disposed in the second regions 100NA, 200NA. The power electrode ES may include a first electrode layer ES1, a second electrode layer ES2 disposed on the first electrode layer ES1 and electrically connected to the first electrode layer ES1, and a third electrode layer ES3 disposed on the second electrode layer ES2 and electrically connected to the second electrode layer ES2. For example, the first electrode layer ES1 is disposed on the same layer as the first connection electrode CNE1 and may include the same material. The second electrode layer ES2 is disposed on the same layer as the second connection electrode CNE2 and may include the same material. The third electrode layer ES3 may be disposed on the same layer as the anode AE described later and may include the same material. The third electrode layer ES3 may be defined as being included in the light emitting element layer 100-3.

The first electrode layer ES1 may be disposed on the third insulating layer 30. A first opening GP1 exposing a portion of the first electrode layer ES1 may be defined in the fourth insulating layer 40. The second electrode layer ES2 may be disposed on the fourth insulating layer 40, and may be disposed in the first opening GP1. In this case, the second electrode layer ES2 may be disposed on the first electrode layer ES1 in the first opening GP1. Accordingly, the second electrode layer ES2 may be electrically connected to the first electrode layer ES1 in the first opening GP1. The fifth insulating layer 50 may be disposed on the fourth insulating layer 40 to cover at least some portions of the second electrode layer ES2. A second opening GP2 exposing a portion of the second electrode layer ES2 may be defined in the fifth insulating layer 50. In this case, the third electrode layer ES3 may be disposed on the second electrode layer ES2 in the second opening GP2. The third electrode layer ES3 may be electrically connected to the second electrode layer ES2 through a second opening GP2.

In addition, first and second dams DM1 and DM2 may be disposed in the second regions 100NA, 200NA. The first dam DM1 may be disposed on the second electrode layer ES2. The second dam DM2 may be disposed on the third insulating layer 30 and be located more outward than the first dam DM1 from the first regions 100A, 200A. In this case, the second dam DM2 may be disposed on a left side of the first dam DM1. Although each of the first dam DM1 and the second dam DM2 has a two-layer structure, the present disclosure is not limited thereto. For example, each of the first dam DM1 and the second dam DM2 may include three or more layers or may have a single-layer structure.

Each of the first dam DM1 and the second dam DM2 includes an upper portion and a lower portion. In this case, the lower portion of the first dam DM1 may be formed through the same process as that of the fifth insulating layer 50. Accordingly, the lower portion of the first dam DM1 may have substantially the same thickness as that of the fifth insulating layer 50 along the third direction DR3 and may include the same material. An upper portion of the first dam DM1 may be formed through the same process as a pixel defining layer PDL. Accordingly, the upper portion of the first dam DM1 may have substantially the same thickness as the pixel defining layer PDL, and may include the same material. According to an embodiment, a third electrode layer ES3 may be interposed between the upper portion of the first dam DM1 and the lower portion of the first dam DM1. The third electrode layer ES3 may be adjacent to the first dam DM1 and may be in contact with portions of the second electrode layer ES2 that are not covered by the first dam DM1.

The lower portion of the second dam DM2 may be formed through the same process as that of the fourth insulating layer 40. Accordingly, the lower portion of the second dam DM2 may have a thickness substantially equal to that of the fourth insulating layer 40 and may include the same material. An upper portion of the second dam DM2 may be formed through the same process as that of the fifth insulating layer 50. Accordingly, the upper portion of the second dam DM2 may have a thickness substantially equal to that of the fifth insulating layer 50 and may include the same material. In this case, the third electrode layer ES3 may be partially interposed between the upper portion and the lower portion of the second dam DM2.

The light emitting element layer 100-3 may be disposed on the circuit layer 100-2. The light emitting element layer 100-3 may include the light emitting element ED and the pixel defining layer PDL.

The light emitting element layer 100-3 may include an organic light emitting material, an inorganic light emitting material, an organic-inorganic light emitting material, a quantum dot, a quantum rod, a micro-LED, or a nano-LED. Hereinafter, although the light emitting element ED is an organic light emitting element, but the present disclosure is not particularly limited thereto.

The light emitting element ED may include an anode AE, a light emitting layer EL, and a cathode CE. The anode AE may be referred to as a first electrode or a pixel electrode, and the cathode CE may be referred to as a second electrode or a common electrode. In this case, the anode AE may be disposed on the fifth insulating layer 50, the emitting layer EL may be disposed on the anode AE, and the cathode CE may be disposed on the emitting layer EL along the third direction DR3.

The anode AE may be connected to the second connection electrode CNE2 through a contact hole penetrating the fifth insulating layer 50. Therefore, the anode AE may be electrically connected to the second transistor TFT-D through the first and second connection electrodes CNE1 and CNE2. The anode AE may include a single-layer structure or multi-layer structure. The anode AE may include a plurality of layers including indium tin oxide (ITO) and silver (Ag). For example, the anode AE may include a layer (hereinafter referred to as a lower ITO layer) including ITO, a layer (hereinafter referred to as an Ag layer) including Ag placed on the lower ITO layer, and a layer (hereinafter referred to as an upper ITO layer) including ITO placed on the Ag layer.

The pixel defining layer PDL may be disposed on the fifth insulating layer 50. An opening OP may be defined in the pixel defining layer PDL. In this case, the pixel defining layer PDL may partially overlap a portion of the anode AE and a portion of the third electrode layer ES3. A portion of the anode AE may be exposed through the opening OP. The light emitting layer EL may be disposed on the exposed anode AE. The light emitting layer EL may include a light emitting material, and may be excited to generate light when an electrical signal is applied to the light emitting layer EL.

The cathode CE may be disposed on the light emitting layer EL and the pixel defining layer PDL. The cathode CE may be disposed on the entire portion of the first regions 100A, 200A and may extend toward the second regions 100NA, 200NA. The cathode CE may be in contact with the power electrode ES to receive the second power signal. For example, the cathode CE may be disposed on the third electrode layer ES3 and in direct contact with the third electrode layer ES3 of the power electrode ES. A region at which the cathode CE is connected to the third electrode layer ES3 may be defined as a connection region CNT-A.

Referring to FIG. 5B, the first region 100A and the connection region CNT-A are provided in the cathode CE. The connection region CNT-A of the cathode CE may have the form of surrounding at least a portion of the first region 100A.

Referring to FIG. 5A, the encapsulation layer 100-4 may be disposed on the light emitting element layer 100-3. According to an embodiment of the present disclosure, the light emitting element layer 100-3 may further include a capping layer to cover the cathode CE. The capping layer is interposed between the encapsulation layer 100-4 and the cathode CE. In this case, the encapsulation layer 100-4 may directly cover the capping layer.

The encapsulation layer 100-4 may include a first inorganic layer 60, an organic layer 70, and a second inorganic layer 80 which are sequentially stacked along the third direction DR3. Although FIG. 5A illustrates that the encapsulation layer 100-4 includes two inorganic layers and one organic layer, the present disclosure is not limited thereto. For example, the encapsulation layer 100-4 may include three inorganic layers and two organic layers. In this case, the inorganic layers and the organic layers may be alternately stacked on each other.

A first inorganic layer 60 may cover the light emitting element layer 100-3, and may extend to a region at which the first dam DM1 and the second dam DM2 are disposed. In this case, the first inorganic layer 60 may disposed on the cathode CE. Hydrophobic or hydrophilic plasma treatment may be performed with respect to the first inorganic layer 60 to control the flow of the organic material to be applied to the first inorganic layer 60, but the present disclosure is not particularly limited thereto. The organic layer 70 may be disposed on the first inorganic layer 60. The organic layer 70 may be formed by depositing, printing, or coating an organic material. According to an embodiment, the organic materials in a liquid phase may be prevented from flowing due to the second opening GP2, the first dam DM1, and the second dam DM2. The second inorganic layer 80 may cover the organic layer 70.

According to an embodiment of the present disclosure, the connection region CNT-A at which the cathode CE is in contact with the third electrode layer ES3 may overlap the first inorganic layer 60, the organic layer 70, and the second inorganic layer 80.

The sensor layer 200 may include a base insulating layer 200-1, a first conductive layer 200-2, a intermediate insulating layer 200-3, a second conductive layer 200-4, and a cover insulating layer 200-5, which may be sequentially overlapped along the third direction DR3. The sensor layer 200 may be formed by a subsequent process after forming the display layer 100. However, the present disclosure is not limited thereto.

The base insulating layer 200-1 may be directly disposed on the display layer 100. For example, the base insulating layer 200-1 may be disposed on the encapsulation layer 100-4 and may be in direct contact with the second inorganic layer 80. The base insulating layer 200-1 may have a single-layer structure or a multi-layer structure. Alternatively, the base insulating layer 200-1 may be omitted.

Each of the first conductive layer 200-2 and the second conductive layer 200-4 may have a single-layer structure or a multi-layer structure stacked in the third direction DR3. The conductive layer having the single layer structure may include a metal layer or a transparent conductive layer. The metal layer may include molybdenum (Mo), silver (Ag), titanium (Ti), copper (Cu), aluminum (Al), and the alloys thereof. The transparent conductive layer may include a transparent conductive oxide, such as indium tin oxide (ITO), indium zinc oxide (IZO), zinc oxide (ZnO), indium tin oxide (IZTO), and the like. In addition, the transparent conductive layer may include a conductive polymer, such as PEDOT, metal nanowires, graphene, and the like.

The conductive layer having the multi-layer structure may include metal layers having the multi-layer structure. The metal layers having the multi-layer structure may have, for example, a three-layer structure of titanium/aluminum/titanium. The conductive layer having the multi-layer structure may include at least one metal layer and at least one transparent conductive layer. However, in another example, the conductive layer may have more than three layers.

Each of the first conductive layer 200-2 and the second conductive layer 200-4 may include patterns constituting sensing electrodes. For example, referring to FIG. 4 together, the first conductive layer 200-2 may include the first connection pattern 212, and the second conductive layer 200-4 may include the first sensing pattern 211, the second sensing pattern 221, and the second connection pattern 222. In addition, each of the first conductive layer 200-2 and the second conductive layer 200-4 may include sensing lines 230. For example, the first conductive layer 200-2 may include some sensing line of the sensing lines 230, and the second conductive layer 200-4 may include other sensing lines of the sensing lines 230.

The intermediate insulating layer 200-3 may be interposed between the first conductive layer 200-2 and the second conductive layer 200-4 to cover the first conductive layer 200-2. Some components of the second conductive layer 200-4 may be electrically connected to some components of the first conductive layer 200-2 through a contact hole penetrating the intermediate insulating layer 200-3. The cover insulating layer 200-5 may be disposed on the intermediate insulating layer 200-3 to cover the second conductive layer 200-4.

At least one of the intermediate insulating layer 200-3 and the cover insulating layer 200-5 may include an inorganic film. The inorganic film may include at least one among aluminum oxide, titanium oxide, silicon oxide, silicon oxynitride, zirconium oxide, or hafnium oxide.

At least one of the intermediate insulating layer 200-3 and the cover insulating layer 200-5 may include an organic film. The organic film may include at least one of an acrylic resin, a methacryl resin, polyisoprene, a vinyl resin, an epoxy resin, a urethane resin, a cellulose resin, a siloxane resin, a polyimide resin, a polyamide resin, or a perylene resin.

According to an embodiment of the present disclosure, at least one of the first conductive layer 200-2 or the second conductive layer 200-4 may include an inspection line TL. Although FIG. 5A illustrates that the first conductive layer 200-2 includes an inspection line TL, the present disclosure is not limited thereto. For example, the second conductive layer 200-4 may include the inspection line TL. In this case, the inspection line TL may have a multi-layer structure and may include the first sub-layer which is included in the first conductive layer 200-2 and the second sub-layer electrically which is connected to the first sub-layer and included in the second conductive layer 200-4.

According to an embodiment of the present disclosure, the inspection line TL may overlap the connection region CNT-A along the third direction DR3. According to an embodiment of the present disclosure, inspection may be made regarding whether the cathode CE of the light emitting element ED and the power electrode ES are stably connected to each other through the inspection line TL. For example, when the capacitance measured using the inspection line TL is within a capacitance range, the cathode CE and the power electrode ES may be determined as being stably connected. Alternatively, when the capacitance measured using the inspection line TL is out of the capacitance range, the contact between the cathode CE and the power electrode ES may be determined as being defective.

A subsequent process may be performed depending on the connection state between the cathode CE and the power electrode ES. For example, when the connection state is determined as being defective, a repair process may be performed. Alternatively, if repair process is not possible or difficult, the manufacturing process for that display panel may be terminated. Accordingly, deterioration of touch performance resulting from the failure in the connection between the cathode CE and the power electrode ES may be prevented. Accordingly, the reliability for the display device 1000 (see FIG. 1) may be improved.

According to an embodiment of the present disclosure, the width WT-1 of the inspection line TL along the first direction DR1 may be subsequently equal to the width WT-2 of the connection region CNT-A along the first direction DR1. Thus, in this case, the inspection line TL may overlap the entirety of the connection region CNT-A along the third direction DR3. The widths WT-1 and WT-2 may be widths formed in a direction crossing in an extension direction of the inspection line TL or widths formed in a direction parallel to a direction in which the inspection line TL is spaced apart from the first regions 100A, 200A.

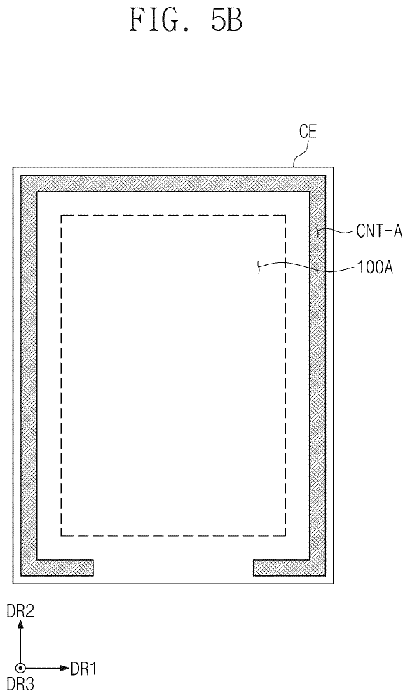

FIG. 6 is a cross-sectional view of a display panel DPa taken line along I-I′ of FIG. 3 and FIG. 4 according to an embodiment of the present disclosure. In the following description made with reference to FIG. 6, the components that are described with reference to FIG. 5A are assigned with the same reference numerals, and the details thereof will be omitted.

The display panel DPa may include a display layer 100 and a sensor layer 200. The sensor layer 200 may include an inspection line TLa which overlaps the connection region CNT-A along the third direction DR3 at which the cathode CE and the power electrode ES are connected to each other.

According to an embodiment of the present disclosure, a width WT-1a of the inspection line TLa along the first direction DR1 may be larger than the width WT-2 of the connection region CNT-A along the first direction DR1. In this case, the inspection line TLa may overlap the entirety of the connection region CNT-A. Accordingly, even if the inspection line TLa is misaligned from the connection region CNT-A, the inspection line TLa may overlap the entire portion of the connection region CNT-A. Accordingly, the failure of the connection region CNT-A may be stably detected through the inspection line TLa. A specific process may be followed (or preformed) with respect to the detected failure. Accordingly, deterioration of touch performance resulting from the failure in the connection between the cathode CE and the power electrode ES may be prevented. Accordingly, the reliability for the display device 1000 (see FIG. 1) may be improved.

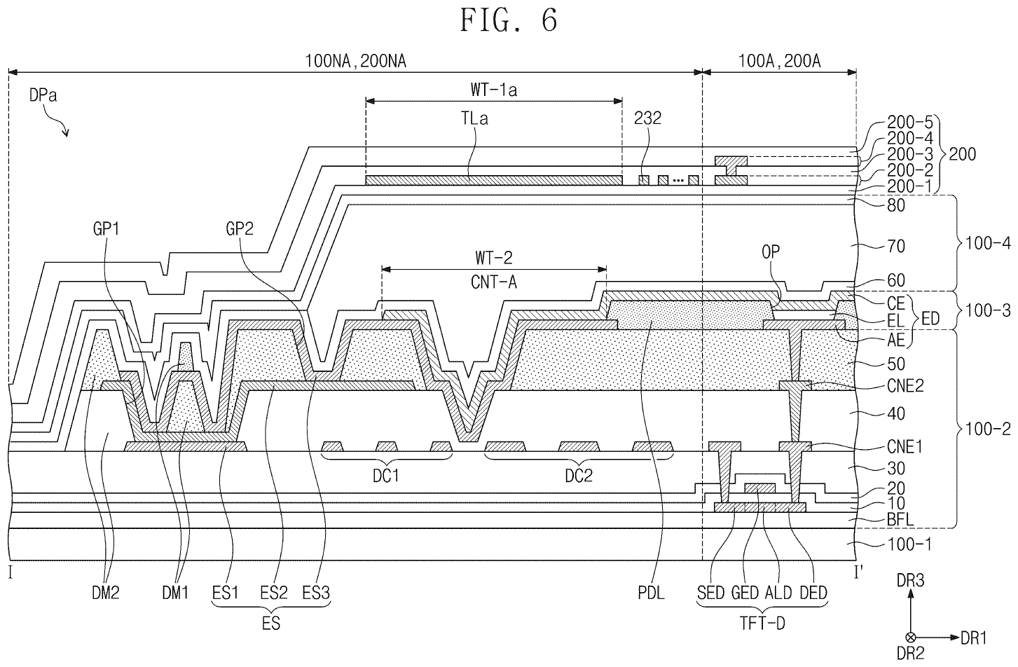

FIG. 7 is a cross-sectional view of a display panel DPb taken line along I-I′ of FIG. 3 and FIG. 4 according to an embodiment of the present disclosure. In the following description made with reference to FIG. 7, the components that are described with reference to FIG. 5A are assigned with the same reference numerals, and the details thereof will be omitted.

Referring to FIG. 7, the display panel DPb may include a display layer 100 and a sensor layer 200. The sensor layer 200 may include an inspection line TLb which overlaps the connection region CNT-A along the third direction DR3 at which the cathode CE and the power electrode ES are connected to each other.

According to an embodiment of the present disclosure, a width WT-1b of the inspection line TLb along the first direction DR1 may be smaller than the width WT-2 of the connection region CNT-A along the first direction DR1. In this case, the inspection line TLb may be sufficiently spaced apart from the sensing lines 232 along the first direction DR1. Accordingly, even if the inspection line TLb is misaligned from the connection region CNT-A, the entire portion of the inspection line TLb may overlap the connection region CNT-A along the third direction DR3. Accordingly, the failure of the connection region CNT-A may be detected by the inspection line TLb. A specific process may be followed (or performed) with respect to the detected failure. Accordingly, deterioration of touch performance resulting from the failure in the connection between the cathode CE and the power electrode ES may be prevented. Accordingly, the reliability for the display device 1000 (see FIG. 1) may be improved.

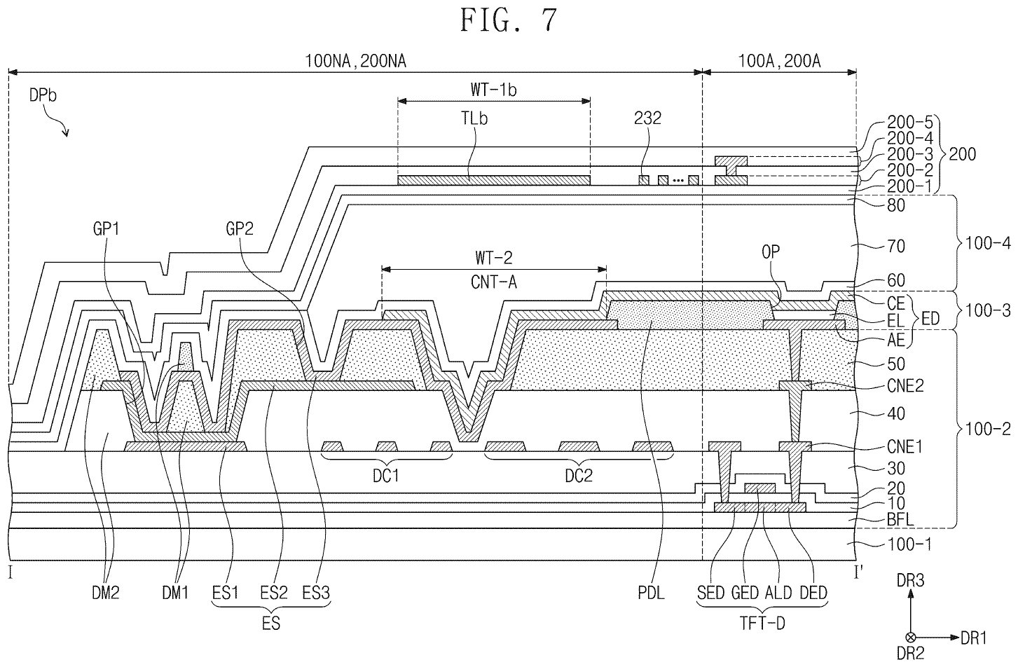

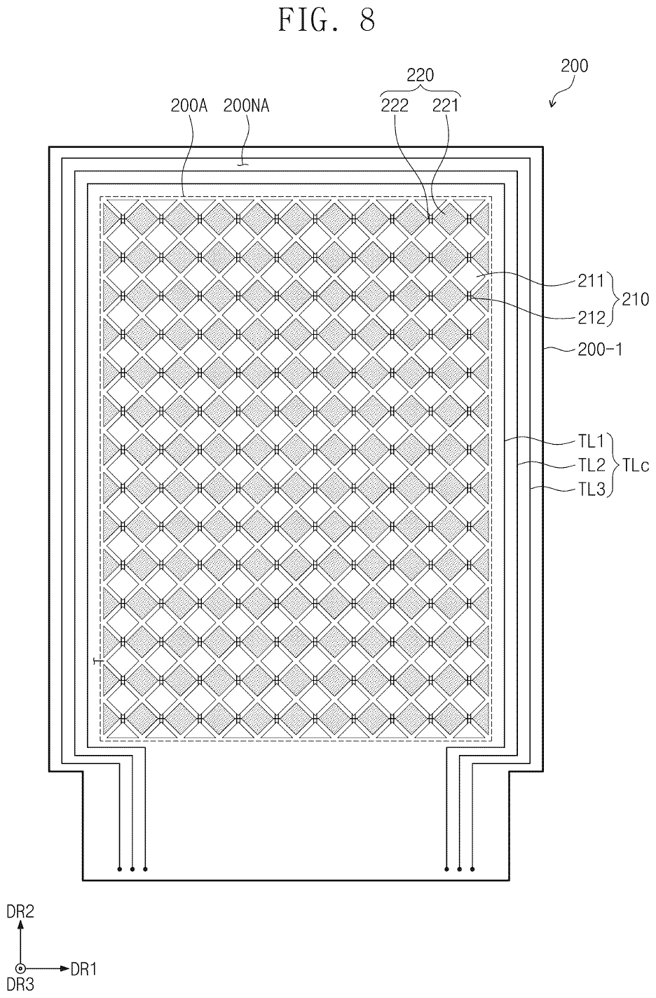

FIG. 8 is a plan view illustrating the sensor layer 200, according to an embodiment of the present disclosure. FIG. 9 is a cross-sectional view of a display panel DPc taken line along I-I′ of FIG. 3 and FIG. 4 according to an embodiment of the present disclosure. In the following description made with reference to FIGS. 8 and 9, the components that are described with reference to FIGS. 4 and 5A are assigned with the same reference numerals, and the details thereof will be omitted.

Referring to FIGS. 8 and 9, the sensor layer 200 may include an inspection line TLc. The inspection lines TLc may include a first inspection line TL1, a second inspection line TL2, and a third inspection line TL3 which overlap the connection region CNT-A along the third direction DR3. Each of the first inspection line TL1, the second inspection line TL2, and the third inspection line TL3 may be disposed on the base insulating layer 200-1 and may be spaced apart from each other in a direction crossing the extension direction of the each of the first inspection line TL1, the second inspection line TL2, and the third inspection line TL3. In this case, each of the first inspection line TL1, the second inspection line TL2, and the third inspection line TL3 may be spaced apart from each other along the first direction DR1. Unlike FIGS. 8 and 9, in another example, less than three or more than three inspection lines TLc may be provided. In addition, each of the first inspection line TL1, the second inspection line TL2, and the third inspection line TL3 may be disposed in the second region 200NA.

The first inspection line TL1 may be disposed along the innermost portion of the second region 200NA and surround at least a portion of the first region 200A. The second inspection line TL2 may be disposed adjacent to the first inspection line TL1 and surround at least a portion of the first region 200A. The third inspection line TL3 may be disposed along the outermost portion of the second region 200NA, disposed adjacent to the second inspection line TL2, and surround at least a portion of the first region 200A. In this case, the second inspection line TL2 may be interposed between the first inspection line TL1 and the third inspection line TL3.

According to an embodiment of the present dis closure, capacitances may be measured from the first to third inspection lines TL1, TL2, and TL3, respectively. Alternatively, when the capacitance measured through the first inspection line to the third inspection line TL1, TL2, and TL3 is out of the capacitance range, the contact between the cathode CE and the power electrode ES may be determined as being defective. The position, which is defective, of the connection region CNT-A may be detected by comparing capacitances measured through the first to third inspection lines TL1, TL2, and TL3. A specific process may be followed (or performed) with respect to the detected failure. Accordingly, deterioration of touch performance resulting from the failure in the connection between the cathode CE and the power electrode ES may be prevented. Accordingly, the reliability for the display device 1000 (see FIG. 1) may be improved.

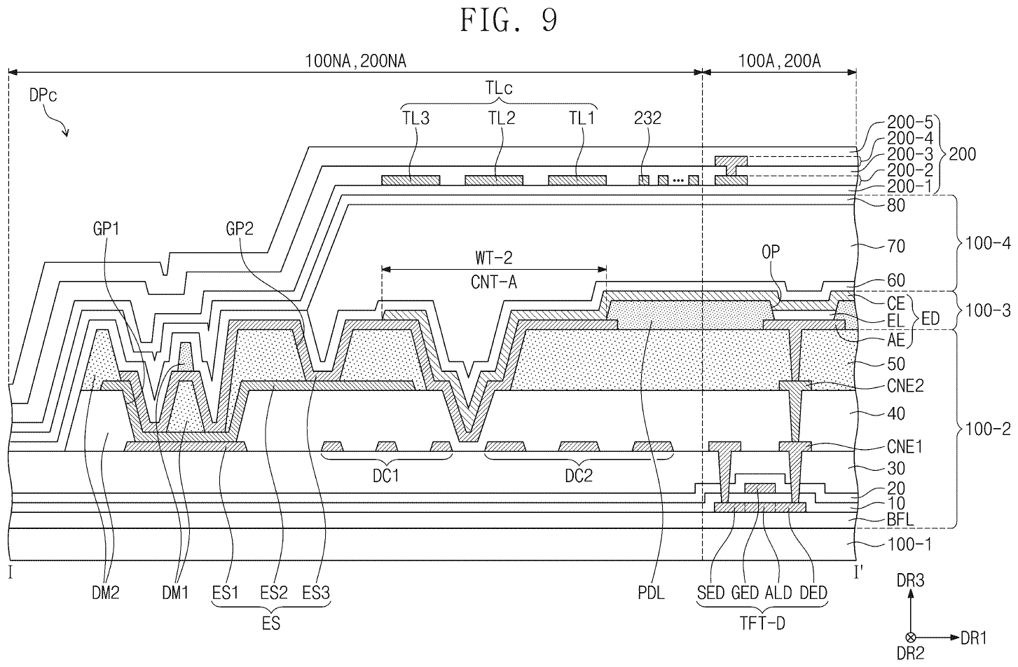

FIG. 10 is a perspective view illustrating some components of a display panel, according to an embodiment of the present disclosure. For example, FIG. 10 illustrates that the cathode CE and inspection lines TLd.

Referring to FIG. 10, the connection region CNT-A may be defined in the cathode CE. The inspection lines TLd may overlap the connection region CNT-A along the third direction DR3. The inspection lines TLd may include a first inspection line TL1a and a second inspection line TL2a.

When viewed in a plan view, the first inspection line TL1a and the second inspection line TL2a may be spaced apart from each other along the first direction DR1 while interposing the first region 100A between the first inspection line TL1a and the second inspection line TL2a. Each of capacitances may be measured through the first and second inspection lines TL1a and TL2a. Alternatively, when the capacitance measured through the first inspection line TL1a and the second inspection line TL2a is out of the capacitance range, the contact between the cathode CE and the power electrode ES may be determined as being defective. The position, which is defective, of the connection region CNT-A may be detected by comparing capacitances measured through the first and second inspection lines TL1a and TL2a. A specific action may be performed with respect to the detected failure. Accordingly, deterioration of touch performance resulting from the failure in the connection between the cathode CE and the power electrode ES may be prevented. Accordingly, the reliability for the display device 1000 (see FIG. 1) may be improved.

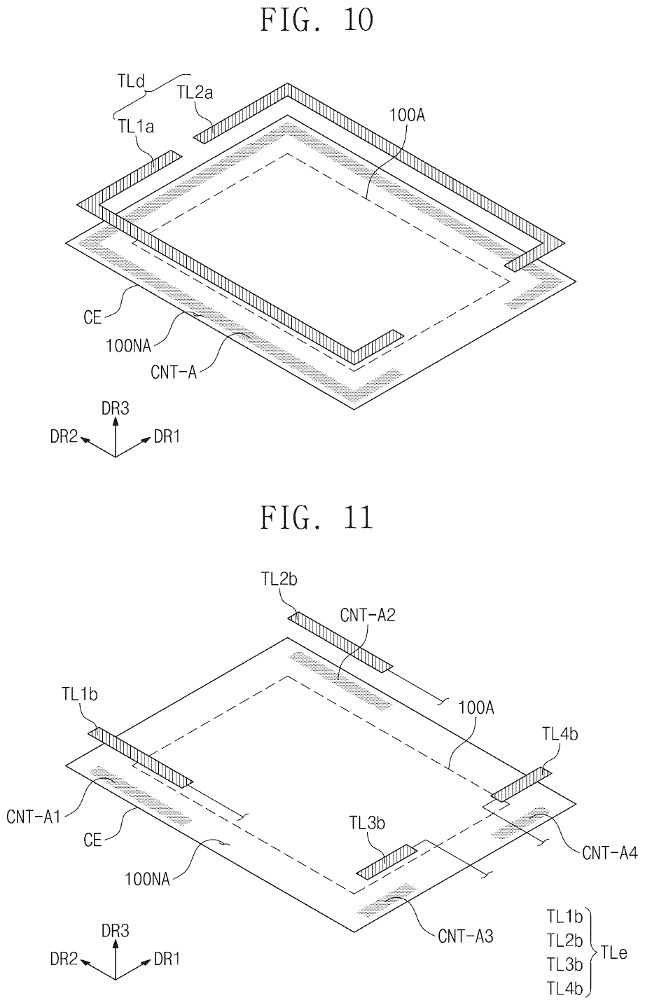

FIG. 11 is a perspective view illustrating some components of a display panel, according to an embodiment of the present disclosure. For example, FIG. 11 illustrates the cathode CE and inspection lines TLe.

Referring to FIG. 11, a plurality of connection areas CNT-A1, CNT-A2, CNT-A3, and CNT-A4 may be defined in the cathode CE. The cathode CE may be in direct contact with the power electrode ES (see FIG. 5A) in each of the connection regions CNT-A1, CNT-A2, CNT-A3, and CNT-A4. The inspection lines TLe may overlap each of the connection regions CNT-A1, CNT-A2, CNT-A3, and CNT-A4 in a one-to-one correspondence along the third direction DR3.

According to an embodiment of the present disclosure, the connection regions CNT-A1, CNT-A2, CNT-A3, and CNT-A4 may include first to fourth connection regions CNT-A1, CNT-A2, CNT-A3, and CNT-A4, and the inspection lines TLe may include first to fourth inspection lines TL1b, TL2b, TL3b, and TL4b. Thus, in this case, the first connection region CNT-A1 may correspond to the first inspection line TL1b, the second connection region CNT-A2 may correspond to the second inspection line TL2b, the third connection region CNT-A3 may correspond to the third inspection line TL3b, and the fourth connection region CNT-A1 may correspond to the fourth inspection line TL4b along the third direction DR3.

Capacitance may be measured through the first to fourth inspection lines TL1b, TL2b, TL3b, and TL4b, respectively. Alternatively, when at least one of capacitances measured using the first inspection line TL1b to the fourth inspection line TL4b is out of the capacitance range, the contact between the cathode CE and the power electrode ES may be determined as being defective. The position, which is defective, of the connection regions CNT-A1, CNT-A2, CNT-A3, and CNT-A4 may be detected by comparing capacitances measured through the first, second, third to fourth inspection lines TL1b, TL2b, TL3b, TL4b A specific process may be followed (or performed) with respect to the detected failure. Accordingly, deterioration of touch performance resulting from the failure in the connection between the cathode CE and the power electrode ES may be prevented. Accordingly, the reliability for the display device 1000 (see FIG. 1) may be improved.

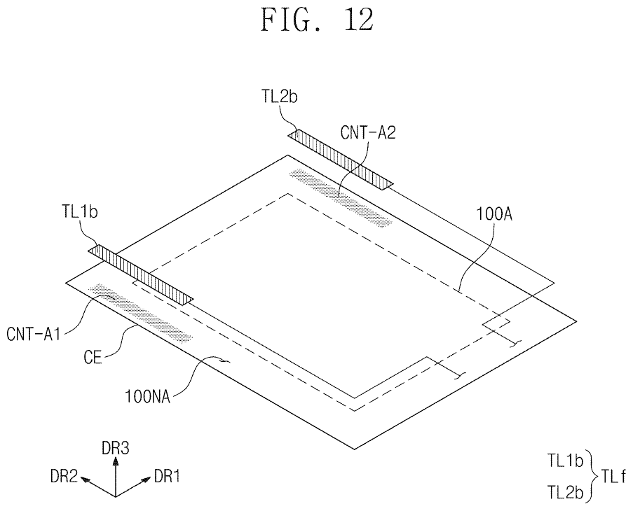

FIG. 12 is a perspective view illustrating some components of a display panel, according to an embodiment of the present disclosure.

Referring to FIG. 12, a plurality of connection regions CNT-A1 and CNT-A2 may include a first connection region CNT-A1 and a second connection region CNT-A2 and may be defined in the cathode CE. Inspection lines TLf may include a first inspection line TL1b and a second inspection line TL2b and may overlap the connection regions CNT-A1 and CNT-A2 in a one-to-one correspondence along the third direction. In this case, the connection regions CNT-A1 may be spaced apart from the second connection region CNT-A2 along the first direction DR1. In addition, the inspection lines TLf may be spaced apart from the second inspection line TL2b along the first direction DR1.

Alternatively, when capacitances measured through the first inspection line TL1b and the second inspection line TL2b, and when one of the capacitances is out of the capacitance range, the contact between the cathode CE and the power electrode ES may be determined as being defective. The position, which is defective, of the connection region CNT-A may be detected by comparing capacitances measured through the first and second inspection lines TL1b, and TL2b. A specific action may be performed with respect to the detected failure. Accordingly, deterioration of touch performance resulting from the failure in the connection between the cathode CE and the power electrode ES may be prevented. Accordingly, the reliability for the display device 1000 (see FIG. 1) may be improved.

As described above, the display device may include the inspection line. The inspection line may be overlapped with the connection region at which the cathode (or a common electrode) of the light emitting element is connected to the power electrode. The connection state between the cathode and the power electrode may be inspected through the inspection line. The subsequent process may be performed depending on the connection state between the cathode and the power electrode. For example, when the connection state is determined as being defective, a repair process may be performed. When the repair process is difficult, the next process is not performed, and the inspection is terminated. Accordingly, deterioration of touch performance resulting from the failure in the connection between the cathode and the power electrode ES may be prevented. Accordingly, the reliability of the display device may be improved.

Although an embodiment of the present disclosure has been described for illustrative purposes, those skilled in the art will appreciate that various modifications, and substitutions are possible, without departing from the scope and spirit of the invention as disclosed in the accompanying claims. Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display layer configured to display an image; and
a sensor layer disposed on the display layer and configured to sense an input,
wherein the display layer includes:
a base layer including a first region and a second region adjacent to the first region, wherein the first region and the second region are defined in the base layer;
a plurality of pixels disposed in the first region of the base layer and including a cathode; and
a power electrode disposed in the second region of the base layer and connected to the cathode at a connection region,
wherein the sensor layer includes a plurality of sensing electrode and an inspection line which overlaps the connection region.

2. The display device of claim 1, wherein the connection region surrounds at least a portion of the first region.

3. The display device of claim 1, wherein a plurality of inspection lines is provided,
wherein the plurality of inspection lines includes a first inspection line and a second inspection line, and
wherein the first inspection line and the second inspection line overlap the connection region in a thickness direction.

4. The display device of claim 3, wherein the first inspection line and the second inspection line are spaced apart from each other, and
wherein the first region is disposed between the first inspection line and the second inspection line, when viewed in a plan view.

5. The display device of claim 3, wherein the first inspection line surrounds at least a portion of the first region, and the second inspection line is spaced apart from the first region while interposing the first inspection line between the second inspection line and the first region, when viewed in a plan view.

6. The display device of claim 1, wherein a width of the inspection line is equal to a width of the connection region.

7. The display device of claim 1, wherein a width of the inspection line is smaller than a width of the connection region.

8. The display device of claim 1, wherein a width of the inspection line is greater than a width of the connection region.

9. The display device of claim 1, wherein a plurality of inspection lines is provided, extend in a first direction, and are arranged in a second direction crossing the first direction.

10. The display device of claim 1, wherein a plurality of connection regions is provided, and a plurality of inspection lines are provided, and
wherein the plurality of inspection lines overlaps the plurality of connection regions in a one-to-one correspondence.

11. The display device of claim 1, wherein the power electrode includes:
a first electrode layer;
a second electrode layer disposed on the first electrode layer and connected to the first electrode layer; and
a third electrode layer disposed on the second electrode layer and connected to the second electrode layer, and
wherein the cathode is in direct contact with the third electrode layer.

12. The display device of claim 11, wherein the inspection line overlaps the third electrode layer in a thickness direction, and
wherein the cathode extends from the first region to the second region.

13. A display device comprising:
a base layer including a first region and a second region adjacent to the first region, wherein the first region and the second region are defined in the base layer;
a power electrode disposed in the second region of the base layer to receive a power supply voltage;
a light emitting element disposed in the first region of the base layer and including an anode, a light emitting layer disposed on the anode, and a cathode disposed on the light emitting layer and electrically connected to the power electrode; and
an inspection line which overlaps a connection region at which the cathode and the power electrode are connected to each other.

14. The display device of claim 13, wherein the power electrode includes:
a first electrode layer;
a second electrode layer disposed on the first electrode layer and connected to the first electrode layer; and
a third electrode layer disposed on the second electrode layer and connected to the second electrode layer, and
wherein the cathode is in direct contact with the third electrode layer.

15. The display device of claim 14, wherein the third electrode layer is disposed on a layer a same as a layer of the anode and includes a same material, and
wherein the inspection line overlaps the third electrode layer in the thickness direction.

16. The display device of claim 13, wherein a plurality of inspection lines is provided,
wherein the plurality of inspection lines includes a first inspection line a second inspection line, and
wherein the first inspection line and the second inspection line overlap the connection region.

17. The display device of claim 16, wherein the first inspection line and the second inspection line are spaced apart from each other, and
wherein the first region is disposed between the first inspection line and the second inspection line, when viewed in a plan view.

18. The display device of claim 16, wherein the first inspection line surrounds at least a portion of the first region and the second inspection line is spaced apart from the first region while interposing the first line between the second inspection line and the first region, when viewed in a plan view.

19. The display device of claim 13, wherein a plurality of connection regions are provided, and a plurality of inspection lines are provided, and
wherein the plurality of inspection lines overlaps the plurality of connection regions in a one-to-one correspondence.

20. A display device comprising:
a base layer;
a power electrode disposed on the base layer to receive a power supply voltage;
a light emitting element disposed on the base layer and including an anode, a light emitting layer, and a cathode electrically connected to the power electrode;
an inspection line which overlaps a connection region at which the cathode and the power electrode are connected to each other; and
an encapsulation layer disposed on the light emitting layer to cover the light emitting element,
wherein the inspection line is disposed on the encapsulation layer.
